(19) United States
(12) Patent Application Publication
(10) Pub. No.: US 2009/0002034 A1
(43) Pub. Date: Jan. 1, 2009

(54) Circuit Arrangement and Method for Detecting a Power Down Situation of a Voltage Supply Source

(75) Inventors: Joen Westendorp, Woerden (NL); Louw Hoefnagel, Veenendaal (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/162,839

(22) PCT Filed: Feb. 5, 2007
(86) PCT No.: PCT/IB2007/050383

§ 371 Date: Aug. 13, 2008

(30) Foreign Application Priority Data
Feb. 9, 2006 (EP) 06101485.8

(51) Int. Cl. H03K 5/22

(52) U.S. Cl. 327/77

(57) ABSTRACT

Circuit arrangement for detecting a power down situation of a second voltage comprising a first conductor, adapted the be connected to a first voltage, a second conductor, adapted the be connected to a reference voltage, an input node, adapted the be connected to the second voltage, and two output nodes, a first output node and a second output node. The output nodes are interconnected in such a manner, that (a) when the second voltage is higher than the reference voltage, the first output node is at the first voltage level and the second output node is at the reference voltage level, and (b) when the second voltage is equal to the reference voltage, the first output node is at the reference voltage level and the second output node is at the first voltage level. The circuit arrangement further comprises an inverter section arranged in between the two conductors, wherein the input node represents an inverter section input and wherein an inverter section output node is formed representing the inverter section output.

The present invention relates to the field of electronic circuits for detecting a voltage level of a voltage supply source. In particular, the present invention relates to a circuit arrangement for detecting a power down situation of a voltage level provided by a voltage supply source. Further, the present invention relates to a method for detecting a power down situation of a second voltage level (Vcc) with a circuit arrangement as described above.

In many electronic devices, e.g. in computers and in particular in main boards of computers there are electronic circuits comprising a plurality of different electronic components. Frequently, some components and/or circuit portions are operated at a first supply voltage level wherein other components and/or circuit portions are operated at a second supply voltage level, which is different from the first supply voltage level.

In order to prevent an irreversible damage of such electronic devices there are known so-called voltage level shifters, which may be used in a modified way such that they can indicate when a power supply voltage passes over into a power down situation.

US 2004/0207450 discloses a voltage level shifter, which comprises a level changer and an output circuit. The level changer has a current block and a first transistor. A high voltage power supply higher than the potential of the low voltage power supply or the current block is connected to a source or a drain of the first transistor. The level changer outputs a potential of the high voltage power supply or a reference potential by a potential of an input signal inputted into the first transistor. The output circuit outputs an output signal having amplitude between the reference potential and the potential of the high voltage power supply when a signal from an output end of the level changer is inputted thereto. However, the state of the output is not determined if one of the two voltage supplies removed. Therefore, the disclosed circuit is not suitable for detecting a power down situation of one of the supply voltage sources.

There may be a need for a circuit arrangement and a method for detecting a power down situation of a voltage supply source.

This need may be met by a circuit arrangement for detecting a power down situation of a second voltage level as set forth in claim 1. According to a first aspect of the invention the circuit arrangement comprises a first conductor, adapted the be connected to a first voltage level, a second conductor, adapted the be connected to a reference voltage level, an input node, adapted the be connected to the second voltage level, and two output nodes, a first output node and a second output node, which are interconnected within the circuit arrangement. The two output nodes are interconnected in such a manner, that (a) when the second voltage level is higher than the reference voltage level, the first output node is at the first voltage level and the second output node is at the reference voltage level, and (b) when the second voltage level is equal to the reference voltage level, the first output node is at the reference voltage level and the second output node is at the first voltage level. The circuit arrangement further comprises an inverter section arranged in between the first conductor and the second conductor, wherein the input node represents an inverter section input and wherein an inverter section output node is formed representing the inverter section output.

This aspect of the invention is based on the idea that a so-called level shifter circuit may be advantageously used as a power down detection circuit, if the level shifter circuit is modified. The modification includes the replacement of a conventional inverter, which is usually included in a level shifter circuit, with an inverter section arranged in between the first and the second conductor. This may provide the advantage that the power down detection is also working reliable when a voltage source providing the second voltage level is completely down, i.e. when the second voltage level is zero volts.

It has to be pointed out that all voltage levels, which are mentioned above and which will be mentioned later in this description might differ slightly from the stated voltage levels due to one or more so-called voltage drops. Such voltage drops may be generated e.g. by pn-transitions in any diode like semiconductor component.

According to an embodiment of the present invention as set forth in claim 2, the reference voltage level is at ground level. This has the advantage that the circuit arrangement might be used in electronic devices, which do not comprise a third voltage level. In particular if the first and the second supply voltage level are positive with respect to the ground level, there is no need for a negative supply voltage for operating the circuit arrangement for power down detection. This makes the circuit arrangement to be operable very easily such that the described power down detection might be applicable in many different electronic devices.

According to a further embodiment of the invention as set forth in claim 3, the second voltage level is lower than the first voltage level. Since many electronic devices require two supply voltage levels, e.g. approximately 3.6 Volt and 1.1 Volt, the described circuit arrangement may be useful for improving the robustness and the life cycle of such devices.

According to a further embodiment of the invention as set forth in claim 4, the circuit arrangement further comprises two first switching elements arranged in series in between the first conductor and the second conductor whereby the first output node is formed in between these two first switching elements and whereby the inverter section output node is connected with one switching element out of these two first switching elements, which switching element is arranged in between the first output node and the second conductor.

Preferably, the two first switching elements are Metal-Oxide-Semiconductor Field Effect Transistors (MOSFET) whereby one MOSFET is a so-called p-channel MOSFET (pmos device) and the other MOSFET is a so-called n-channel MOSFET (nmos device). Since both MOSFET devices are used in a complementary way the switching elements are also called CMOS switching elements.

CMOS switching elements provide the advantage that only a very small stationary current flows from the first conductor to the second conductor when at least one switching element arranged in each branch between the two conductors is closed. Therefore, electronic devices with a very low power consumption may be built up.

According to a further embodiment of the invention as set forth in claim 5, the circuit arrangement further comprises two second switching elements arranged in series in between the first conductor and the second conductor whereby the second output node is formed in between these two second switching elements. Preferably, also the second switching elements are also so-called CMOS switching elements having the advantage that a only a very low stationary current flows from the first conductor to the second conductor.

According to a further embodiment of the invention as set forth in claim 6, the inverter section comprises two third switching elements arranged in series in between the first conductor and the second conductor whereby the inverter section output node is formed in between these two third switching elements. This embodiment has the advantage that the inverter may be built up very easy such the production costs of such a power down situation detecting device may be reduced.

Further, apart from the first voltage level the presence of the second voltage level is not needed in order to make the power down detection of the second voltage level working reliably. As has already been mentioned above, preferably CMOS switching elements may be used for the third switching elements having the above described advantage of a low static current.

According to a further embodiment of the invention as set forth in claim 7, the circuit arrangement further comprises a fourth switching element. The fourth switching element is connected in between the first output node and the second conductor in such a manner that the first output node is capable of being at least partially discharged when the second voltage level accomplishes a shift from the voltage level higher than the reference voltage level to the reference voltage level. The fourth switching element, which preferably is arranged in parallel to the third switching element, may allow for a faster discharging of the first output node in the event of an abrupt power down situation of the second voltage. This may provide the advantage that the power down detection becomes faster and more reliable.

In this context it is stated that the discharging may further be speeded up due to a discharge amplification effect provided by a loop formed by the second conductor and the inverter section and in particular by the second conductor and the inverter section output node.

According to a preferred embodiment of the invention as set forth in claim 8, the circuit arrangement further comprises a current mirror section, wherein a first current mirror node of the current mirror section is connected with the fourth switching element. This may have the advantage that the current mirror provides a stable and reliable control for the fourth switching element.

In this embodiment of the invention a modified level shifter circuit and a current mirror circuit are combined in an advantageous way. This has the advantage that the circuit arrangement always is in an electronically defined state (i.e. no floating nodes) even when the supply source of the second voltage supply level is completely failed and the second voltage level is at ground level.

According to a further embodiment of the invention as set forth in claim 9, the current mirror section comprises a first branch and a second branch whereby both branches are arranged in between the first conductor and the second conductor. Therefore, the set up of the current mirror section corresponds to the well-known current mirror setup.

According to a further embodiment of the invention as set forth in claim 10, two fifth switching elements are arranged in series within the first branch and a second current mirror node is formed in between these two fifth switching elements. Again, preferably CMOS switching elements may be used for the fifth switching elements such that a small stationary current may be generated leading to a low power consumption and, as a consequence, to a low heat development within an electronic device which includes the described circuit arrangement for a reliably power down detection.

According to a further embodiment of the invention as set forth in claim 11, at least two sixth switching elements are arranged in series within the second branch and the first current mirror node is formed in between these two sixth switching elements.

According to a further embodiment of the invention as set forth in claim 12, four sixth switching elements are arranged within the second branch whereby three sixth switching elements out of these four sixth switching elements are arranged in series in between the first conductor and the first current mirror node and one sixth switching element out of these four sixth switching elements is arranged in between the first current mirror node and the second conductor. This may provide the advantage that a middle switching element out of these three sixth switching elements arranged in series in between the first conductor and the first current mirror node effectively represents a current limiter. Therefore, the stationary current flowing through the second branch is reduced significantly leading to the above-mentioned beneficial properties of the entire power down detection circuit. Since in the current mirror the stationary current flowing through the first branch has the same reduced amperage the total power dissipated by the current mirror may be reduced by a factor of two.

According to a further embodiment of the invention as set forth in claim 13, two sixth switching elements, which both are directly connected to the first current mirror node are controlled by the second voltage level. The connections between the second voltage level and these two switching elements, respectively, may have the advantage that in case of an abrupt voltage drop of the second voltage level down to ground voltage level the voltage level of the first current mirror node will be enhanced and, as a consequence, the fourth switching element will open leading to a discharge current flowing from the first output node to ground. Therefore, the temporal coarse of the voltage level being present at the first output node will follow the temporal coarse of second voltage level more quickly and in a more reliably way. As a consequence, the entire power down detection will be faster and more reliably.

The above-mentioned need may further be met by a method as set forth in claim 14. According to this aspect of the invention there is provided a method for detecting a power down situation of a second voltage level with any of the circuit arrangements, which have been described above. The method comprises the following characteristic steps:

(a) changing the voltage level of the first output node from the first voltage level to the reference voltage level and (b) changing the voltage level of the second output node from the reference voltage level to the first voltage level
when the second voltage level accomplishes a shift from a voltage level higher than the reference voltage level to the reference voltage level, and
(a) changing the voltage level of the first output node from the reference voltage level to the first voltage level and (b) changing the voltage level of the second output node from the first voltage level to the reference voltage level
when the second voltage level accomplishes a shift from the reference voltage level to a voltage level higher than the reference voltage level. The method advantageously allows for a reliable power down detection with a low power consumption. The low power consumption is related to low static currents within the circuit.

According to an embodiment of the invention as set forth in claim 15, the first output node is at least partially discharged, when the second voltage level accomplishes a shift from the voltage level higher than the reference voltage level to the reference voltage level. The discharging is assisted by of a fourth switching element, which is connected in between the first output node and the second conductor.

The fourth switching element, which preferably is arranged in parallel to the third switching element, may allow for a faster discharging of the first output node. Therefore, a power down detection of the second voltage level is much faster and much more reliable because the output signal at the first output node can follow a change of the input signal much faster. Therefore, the power down detection is both faster and more reliable.

It has to be noted that certain embodiments of the invention have been described with reference to circuit arrangements and other embodiments of the invention have been described with reference to methods for detecting a power down situation. However, a person skilled in the art will gather from the above and the following description that, unless other notified, in addition to any combination of features belonging to one category of claims also any combination between features of the method claims and features of the circuit claims is possible and is disclosed with this application.

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

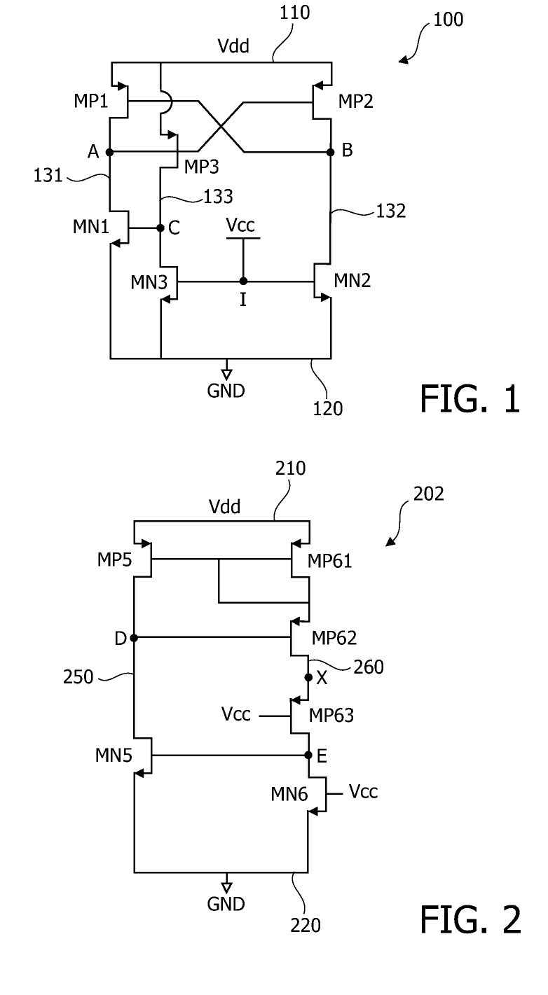

FIG. 1 shows an extended level shifter adapted to detect a power down situation of a second supply voltage Vcc.

FIG. 2 shows a current mirror including a current limiting switching element, which current mirror is adapted to be combined with the extended level shifter shown in FIG. 1 in order to build up an even more reliable circuit for detecting a power down situation.

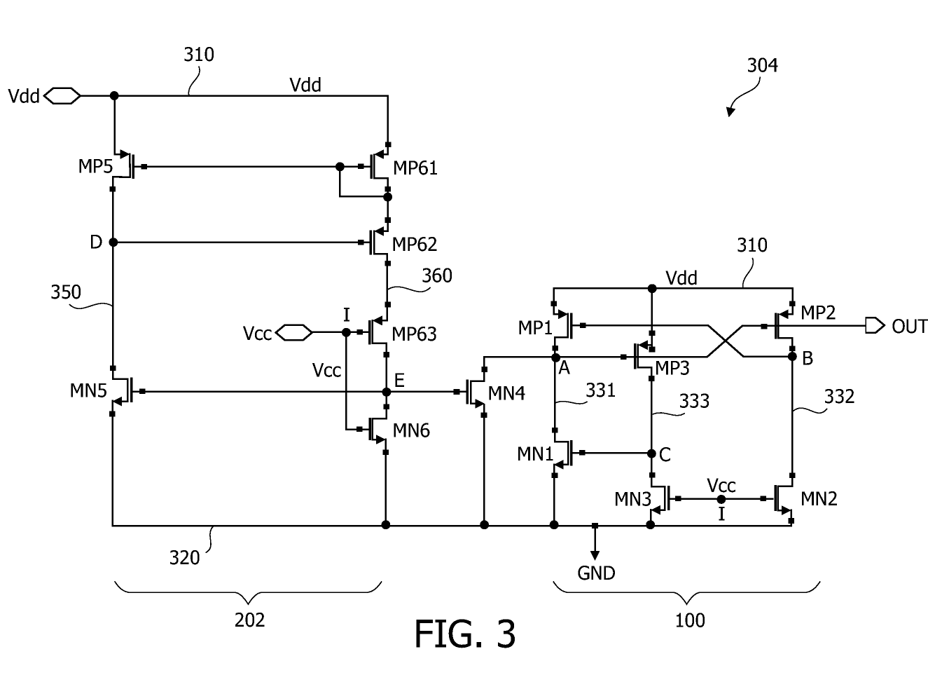

FIG. 3 shows a circuit diagram of an improved power down detection circuit arrangement.

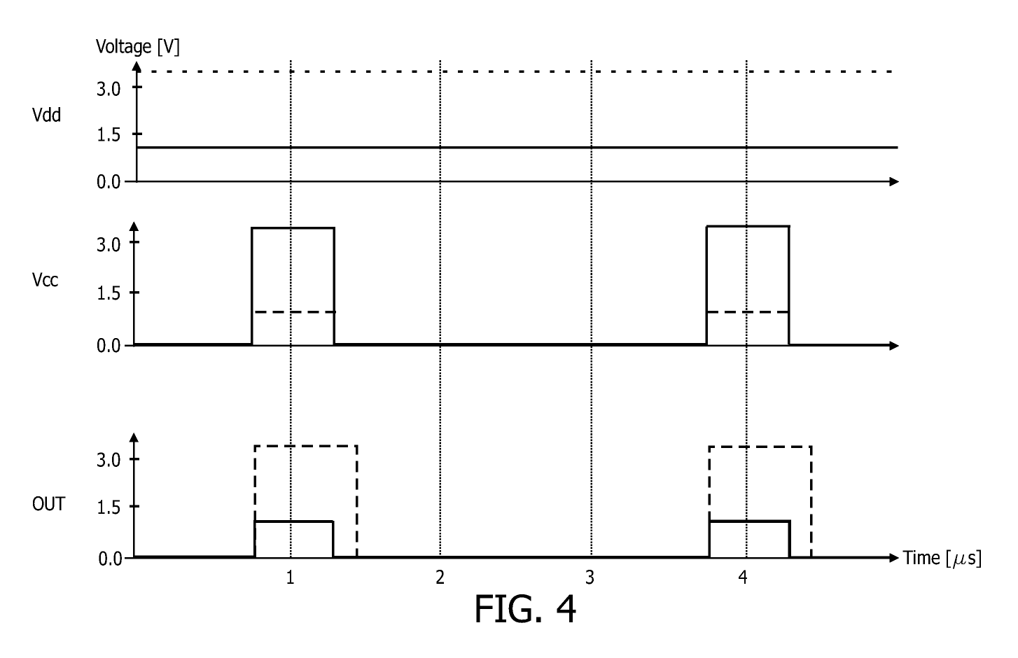

FIG. 4 shows diagrams depicting the temporal behavior of the output shown in FIG. 3 when the voltage level Vcc is varied in a stepwise manner.

The illustration in the drawing is schematically. It is noted that in different drawings, similar or identical elements are provided with the same reference signs or with reference signs, which are different from the corresponding reference signs only within the first digit.

FIG. 1 shows a power down detection circuit arrangement 100 according to an embodiment of the invention. The setup of the circuit arrangement 100 is based on a so-called conventional level-shifter. The circuit 100 comprises a first conductor 110, which is connected to a voltage supply source (not shown) providing a first supply voltage Vdd. The circuit 100 further comprises a second conductor 120, which is connected to ground GND.

In between the first conductor 110 and the second conductor 120 there are formed three branches, a left branch 131, a right branch 132 and a middle branch 133. The left branch 131 comprises a pmos switch MP1 and an nmos switch MN1, which are arranged in series with respect to each other. In between these two switches MP1 and MN1 there is formed a first output node A. The right branch 132 comprises a pmos switch MP2 and an nmos switch MN2, which are also arranged in series with respect to each other. In between these two switches MP2 and MN2 there is formed a second output node B.

The source contacts of the two pmos switches MP1 and MP2, respectively, are both connected to the first conductor 110. As can be seen from FIG. 1 the gate contacts and the drain contacts of the two pmos switches MP1 and MP2, respectively, are coupled in a cross wise manner with each other. Therefore, the gate of MP1 is connected with the second output node B and the gate of MP2 is connected with the first output node A.

The middle branch 133 comprises a pmos switch MP3 and an nmos switch MN3. In between these two switches MP3 and MN3 there is formed a node C. This node C is denoted an inverter section second output node because the two switches MP3 and MN3 effectively form an inverter section, which comprises the gate of MN3 as an input and the node C as an output. The inverter formed by MP3 and MN3 will be described later on.

The gates of MN3 and MN2 are both connected to an input node I, which itself is connected to a voltage supply source (not shown) providing a second supply voltage Vcc. The gate of MP3 is connected with the first output node A and with the gate of MP2, respectively.

In order to detect the power situation of the voltage supply source providing Vcc, Vcc is applied to the input node I of the circuit 100. As one can be see from the forthcoming description the voltage levels of the first output node A and the second output node B, respectively, indicate the power situation of Vcc. Therefore, in order to understand the power down detection modus of the circuit 100 one has to become clear what happens when Vcc is toggled.

At this point the typical behavior of pmos and nmos switches in digital electronics is briefly recapitulated in a simplified manner: A pmos switch is open when a low voltage state is applied to its gate and the pmos switch is closed when a high voltage state is applied to its gate. Accordingly, an nmos switch is closed when a low voltage state is applied to the gate of the nmos device and the nmos switch is open when a high voltage state is applied to its gate.

If the voltage source supplying Vcc is working, i.e. the voltage level Vcc is well above ground, the two nmos switches MN2 and MN3 will be in the opened state. Therefore, the second output node B and the inverter section output node C will be pulled low to ground level GND. The low state of node C will cause a charging of the first output node A until this node A is at a voltage level of Vdd. The cross coupled configuration of the pmos switches MP1 and MP2 ensures that the voltage level of the second output node B is always the inverted voltage level of the voltage level of the first output node A. Therefore, when Vcc is well above ground GND the voltage level of the second output node B is low. This approves the low state of node B, which already has been defined as low because of the open state of MN2. Therefore, the depicted cross coupling of MP1 and MP2 makes the output states to defined more decided.

If the voltage source supplying Vcc has a failure, i.e. the voltage level Vcc drops to a voltage level corresponding to ground GND, the nmos switches MN2 and MN3 will shut off allowing node B and node C to rise to Vdd. This will cause the nmos device MN1 to open which in turn causes the first output node A to drop to zero volts such that node A is at ground level GND.

In the circuit arrangement 100 the pmos device MP3 and the nmos device MN3 represent an inverter. Thereby, node I is the inverter input and node C is the inverter output.

If Vcc is well above ground level GND, MN2 will be open such that node B is at a low voltage state. This causes the pmos device MP1 to be open such that node A will be at Vdd. Further, Node A is connected to the gate of the pmos switch MP3. Therefore, MP3 will be closed. Furthermore, MN3 is open because Vcc is well above ground level GND. As a consequence of a closed MP3 and an open MN3 the voltage level at node C is low.

On the other hand, if Vcc is at ground level GND, MN2 will be closed such that node B is at a high voltage state. This causes the pmos device MP1 to be closed such that node A will be at ground level GND. Node A is connected to the gate of the pmos switch MP3. Therefore, MP3 will be opened. Further, MN3 is closed because Vcc is at ground level GND. As a consequence of an open MP3 and a closed MN3 the voltage level at node C is high.

As can be seen from the above given description of the switching states of the pmos and the nmos devices included in the circuit 100, in each of the branches 131, 132 and 133 there is always at least one closed switch. This rule applies independent of the power situation of the voltage supply source providing Vcc. As a consequence, the circuit 100 allows only very small static currents flowing from the first conductor 110 to the second conductor 120. This has the advantage that the overall power consumption of the power down detecting circuit is very low. Therefore the circuit 100 can be implemented in a variety of different applications such that the corresponding electronic devices become more reliable and less error-prone because a failure of a voltage supply source providing Vcc can be detected reliably.

FIG. 2 shows a circuit 202 representing a modified current mirror section. As will be seen in the forthcoming description of a further improved power down detection circuit 304 depicted in FIG. 3 the current mirror section 202 will be useful in order to build up such an improved circuit 304.

The current mirror section 202 comprises a first conductor 210, which is connected to a voltage supply source (not shown) providing a first supply voltage Vdd. The circuit 202 further comprises a second conductor 220, which is connected to ground GND.

In between the first conductor 210 and the second conductor 220 there are formed two branches, a first branch 250 and a second branch 260. The first branch 250 comprises a pmos switch MP5 and an nmos switch MN5, which are arranged in series with respect to each other. In between these two switches MP5 and MN5 there is formed a second current mirror node D. The second branch 260 comprises three pmos switches MP61, MP62 and MP63 and one nmos switch MN6. The devices MP61, MP62, MP63 and MN6 are arranged in series. In between the two switches MP63 and MN6 there is formed a first current mirror node E.

The gate of MP62 is connected with node D. The gate of MN5 is connected with node E. The gate of MP63 and the gate of MN6 are both connected to Vcc.

As can be seen from FIG. 2, the source of MP5 and the source of MP61 are both connected to Vdd. Further, the gate of MP5, the gate of MP61 and the drain of MP61 are connected with each other. Therefore, the top portion of the current mirror section 202 including the two pmos devices represents a simple current mirror, which is well known by common textbooks teaching the art of electronics. Since with MOSFET devices the currents flowing through the gates of the switches MP5, MN5, MP61, MP62, MP63 and MN6 are negligible, the current mirror ensures that the current flowing through the first branch 250 has exactly the same amperage as the current flowing through the second branch 260. Thereby, the current flowing through the second branch 260 serves as a reference current.

However, the circuit 202 does not only represent a current mirror. The circuit also represents an inverter. Thereby, Vcc, which is supplied to the gates of MP63 and MN6, is the input and node E is the output. If Vcc is well above ground level GND, MN6 will be open and MP63 will be closed. Therefore, node E is at ground level GND. If Vcc is at ground level GND, MN6 will be closed and MP63 will be opened. In that case, the node E will be at a high voltage level.

In order to guarantee a small static current flowing through both branches 250 and 260, a current limiting is provided. The current limiting can be understood from the following description, where it is assumed that Vdd is equal to approximately 3.6 Volt and Vcc is equal to approximately 1.1 Volt.

If Vcc is present at the gate of MN6, this nmos switch MN6 is open causing node E to be at ground level GND. This causes MN5 to be closed. Therefore, no current will flow through any of the two branches 250 and 260, because there is no voltage difference between node E and ground GND. This means that apart from voltage drops caused by the semiconductor devices MP61 and MP62 a node X, which is located between MP62 and MP63, is almost at a voltage level of 3.6 Volts.

However, MP63 will open at least partially because Vcc is too small to completely close MP63. This causes a current to flow through the second branch 260 to ground GND (MN6 is still open). This current is mirrored to the first branch 250. Since E is still at GND also MN5 is closed. This leads to a charging of node D such that the voltage level at node D will rise. This voltage level increase at node D will cause MP62 to close at least partially such that the current flowing through branch 260 will be reduced. After a static current situation has been established the pmos switch MP62 represents a current limiter. As a consequence, the static currents flowing through both branches 250 and 260 are reduced significantly.

FIG. 3 shows an improved power down detection circuit arrangement 304, which comprises a power down detection circuit arrangement 100 as depicted in FIG. 1 and a current mirror section 202 as depicted in FIG. 2. Although depicted as separate conductors, the circuit 304 comprises a common first conductor 310 providing a first supply voltage Vdd for both circuits 202 and 100. Further, the circuit 304 comprises a second conductor 320 providing a common ground GND.

It has to be noted that the denotation of the various MOSFET devices and the various nodes correspond to the denotation of the MOSFET devices and the nodes shown in FIGS. 1 and 2, respectively.

The circuit arrangement 304 further comprises a common node I for applying the second supply voltage Vcc to the gates of MP63, MN6, MN3 and MN2, respectively. Since a power down detection of the second supply voltage Vcc is carried out by the circuit arrangement 304, the separately depicted nodes I represent a common input to the power down detection circuit 304.

The improved power down detection circuit 304 further comprises an nmos switching device MN4, which is arranged in between the two circuits 202 and 100. Thereby, the drain contact of MN4 is connected to the first output node A known from FIG. 1, the gate of MN4 is connected to the first current mirror node E known from FIG. 2 and the source of MN4 is connected to ground GND. The influence of the nmos switch MN4 will be described later on.

For detecting the power situation of Vcc the circuit comprises an output OUT, which is connected to the gate of MP2, to the gate of MP3, to the first output node A and to the drain of MN4. As has already been elucidated in the description of the circuit 100 (shown in FIG. 1), if the second supply voltage is well above GND, the voltage level at node A and at the output OUT will be Vdd, respectively. By contrast thereto, if Vcc is at ground level GND, the node A and the output OUT will be at GND level, respectively.

In this paragraph the influence of the switching device MN4 will be explained: When Vcc accomplishes an abrupt shift from a voltage level significant higher than ground level GND (e.g. Vcc=1.1 V) down to ground level GND, both nmos switches MN3 and MN2 will be closed. Therefore, neither node B nor node C can be discharged. However, as has already been elucidated in the description of the circuit 202 (shown in FIG. 2), if Vcc drops down to ground level GND, MN6 will be closed and MP63 will be opened. In that case, the node E will be at a high voltage level. Therefore, the nmos device NM4 will open such that the first output node A and also the output OUT will be discharged such that the corresponding voltage level decreases. In addition to this, if the voltage at node A falls below the switching voltage of the inverter formed by MP3 and MN4 such that the pmos switch MP3 opens, node C will be charged up to Vdd. This will cause MN1 to pass over in an open state such that the discharging of the first output node A is accelerated.

Therefore, the nmos device MN4 driven by node E of the current mirror section 202 and arranged parallel to the nmos switch MN1 of the circuit 100, allows for a faster discharging of the first output node A in the event of an abrupt power down situation of Vcc. This has the advantage that the power down detection of the improved power down detection circuit 304 is even faster and more reliable compared to the power down detection circuit 100.

The improved power down detection circuit 304 has the advantage that independent of the presence of Vcc in each of the five branches 331, 332, 333, 350 and 360 there is always at least one switching device closed. Therefore, the static current flowing from the first conductor 310 to the second conductor is very low. This behavior has been verified with Direct Current (DC) simulations. The simulations apply for MOSFET devices, which have been produced be means of a so-called 350 nm diffusion process wherein gates with a length of 350 nm are formed. The results of these simulations, which have been carried out for different combinations of Vdd and Vdd, are shown in Table 1.

TABLE 1
DC simulation of the improved power down detection circuit 304 as a
function of different supply voltages Vdd and Vcc.

| | Vdd [V] | | | | | | | | |
|---|---|---|---|---|---|---|---|---|---|
| | 0 | | | 1.1 | | | 3.6 | | |
| Vcc [V] | 0 | 1.1 | 3.6 | 0 | 1.1 | 3.6 | 0 | 1.1 | 3.6 |
| I (Vdd) [nA] | 0 | 0 | 0 | 2.1 | 1.0 | 3.6 | 8.9 | 1.0 | 3.6 |
| I (Vcc) [nA] | 0 | 0 | 0 | 0 | 0 | 0 | 0 | 0 | 0 |

Thereby, I (Vdd) represents the current drawn from Vdd given in 10⁻⁹ ampere (nA). I (Vcc) represents the current drawn from Vcc also given in nA. One can see, that in any case I (Vcc) is below 1 nA. It has been found out that I (Vcc) is in the range of 10⁻¹⁵ ampere (fA). The reason for this low static current I (Vcc) is that the second supply voltage Vcc is connected only to gates of nmos and pmos devices, which are electrically isolated from the source and the drain contacts of these devices, respectively.

FIG. 4 shows the results of transient simulations of the behavior of the output OUT when the input signal Vcc is ramped up and down. Different voltage levels are plotted versus the time. The scale unit of the voltage-axis is Volt (V). The scale unit of the time-axis is 10⁻⁶ seconds (μs). Two different situations are depicted: The dashed line shows the behavior of the output OUT for a first supply voltage level Vdd equal 3.6 V and abrupt changes of Vcc between 0 V and 1.1 V. The full line shows the OUT signal for Vdd equal 1.1 V and abrupt changes of Vcc between 0 V and 3.1 V.

As one can see from the depicted transients, if the Vcc is ramped up, the output OUT is also ramped up. If Vcc is removed, the output OUT goes also to a low voltage level state. The voltage level of the output OUT never exceeds the voltage level of the first supply voltage Vdd. This holds even when the Vcc is ramped up to a voltage level higher than Vdd (see dashed lines).

It has to be pointed out that the improved power down detection circuit 304 is able to put all outputs, in particular the output OUT into an high-impedance mode if the second supply voltage level Vcc passes over to ground level GND.

The improved power down detection circuit 304 can be used generally in any electronic device with two supply voltage sources providing different supply voltages Vdd and Vcc wherein some action is needed depending on the presence of these supply voltages.

It should be noted that the invention is not limited to the exemplary examples shown in the figures. In particular, it is clear for a person skilled in the art that the invention may be realized also with other switching devices like ordinary transistors or other types of Field Effect Transistors (FET), e.g. Junction FET. It is also clear that the invention can also be realized when, in the circuits 100, 202 and 304 shown in FIG. 1, FIG. 2 and FIG. 3, respectively, a pmos device is replaced by an nmos devise and vice versa.

It should be further noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

### LIST OF REFERENCE SIGNS

100 power down detection circuit arrangement
110 first conductor
120 second conductor
131 left branch
132 right branch
133 middle branch
Vdd first supply voltage
Vcc second supply voltage
GND Ground
I input node
A first output node
B second output node
C inverter section output node
MP1 pmos switch
MN1 nmos switch
MP2 pmos switch
MN2 nmos switch
MP3 pmos switch
MN3 nmos switch
202 current mirror section
210 first conductor
220 second conductor
250 first branch
260 second branch
Vdd first supply voltage
Vcc second supply voltage
GND Ground
E first current mirror node
D second current mirror node
X node
MP5 pmos switch
MN5 nmos switch
MP61 pmos switch
MP62 pmos switch
MP63 pmos switch
MN6 nmos switch
304 improved power down detection circuit arrangement
310 first conductor
320 second conductor
331 left branch of circuit 100
332 right branch of circuit 100
333 middle branch of circuit 100
350 first branch
360 second branch
Vdd first supply voltage
Vcc second supply voltage
GND Ground
I input node
A first output node
OUT output
B second output node
C inverter section output node
E first current mirror node
D second current mirror node
MP1 pmos switch
MN1 nmos switch
MP2 pmos switch
MN2 n-CMOS switch
MP3 pmos switch
MN3 nmos switch
MN4 nmos switch
MP5 pmos switch
MN5 nmos switch
MP61 pmos switch
MP62 pmos switch
MP63 pmos switch
MN6 nmos switch

1. Circuit arrangement for detecting a power down situation of a second voltage level, the circuit arrangement comprising
a first conductor, adapted the be connected to a first voltage level,
a second conductor (120), adapted the be connected to a reference voltage level,
an input node, adapted the be connected to the second voltage level,
a first output node and a second output node, which are interconnected within the circuit arrangement in such a manner, that
when the second voltage level his higher than the reference voltage level,
the first output node is at the first voltage level and
the second output node is at the reference voltage level, and
when the second voltage level is equal to the reference voltage level,
the first output node is at the reference voltage level and
the second output node is at the first voltage level, and
an inverter section arranged in between the first conductor and the second conductor,
wherein the input node represents an inverter section input and
wherein an inverter section output node his formed representing the inverter section output.

2. Circuit arrangement according to claim 1, wherein the reference voltage level is at ground level.

3. Circuit arrangement according to claim 1, wherein the second voltage level is lower than the first voltage level.

4. Circuit arrangement according to claim 1, further comprising
two first switching elements arranged in series in between the first conductor and the second conductor
whereby the first output node is formed in between these two first switching elements and
whereby the inverter section output node is connected with one switching element out of these two first switching elements, which switching element is arranged in between the first output node and the second conductor.

5. Circuit arrangement according to claim 1, further comprising
two second switching elements in series in between the first conductor and the second conductor
whereby the second output node is formed in between these two second switching elements.

6. Circuit arrangement according to claim 1, wherein the inverter section comprises
two third switching elements arranged in series in between the first conductor and the second conductor whereby
the inverter section output node is formed in between these two third switching elements.

7. Circuit arrangement according to claim 1, further comprising
a fourth switching element, which is connected in between the first output node and the second conductor in such a manner that the first output node is capable of being at least partially discharged when the second voltage level accomplishes a shift from the voltage level higher than the reference voltage level to the reference voltage level.

8. Circuit arrangement according to claim 7, further comprising
a current mirror section, wherein a first current mirror node of the current mirror section is connected with the fourth switching element.

9. Circuit arrangement according to claim 8, wherein
the current mirror section comprises a first branch and a second branch whereby both branches are arranged in between the first conductor and the second conductor.

10. Circuit arrangement according to claim 9, wherein
two fifth switching elements are arranged in series within the first branch and
a second current mirror node is formed in between these two fifth switching elements.

11. Circuit arrangement according to claim 9, wherein
at least two sixth switching elements are arranged in series within the second branch and
the first current mirror node is formed in between these two sixth switching elements.

12. Circuit arrangement according to claim 11, wherein
four sixth switching elements are arranged within the second branch whereby
three sixth switching elements out of these four sixth switching elements are arranged in series in between the first conductor and the first current mirror node and
one sixth switching element out of these four sixth switching elements is arranged in between the first current mirror node and the second conductor.

13. Circuit arrangement according to claim 12, wherein
two sixth switching elements which both are directly connected to the first current mirror node are controlled by the second voltage level.

14. Method for detecting a power down situation of a second voltage level with a circuit arrangement according to claim 1, the method comprising the steps of
when the second voltage level accomplishes a shift from a voltage level higher than the reference voltage level to the reference voltage level
changing the voltage level of the first output node (A) from the first voltage level to the reference voltage level and
changing the voltage level of the second output node from the reference voltage level to the first voltage level and
when the second voltage level accomplishes a shift from the reference voltage level to a voltage level higher than the reference voltage level
changing the voltage level of the first output node from the reference voltage level to the first voltage level and
changing the voltage level of the second output node from the first voltage level to the reference voltage level.

15. Method according to claim 14, wherein
when the second voltage level accomplishes a shift from the voltage level higher than the reference voltage level to the reference voltage level the first output node is at least partially discharged by means of a fourth switching element, which is connected in between the first output node and the second conductor.
